(19) United States
(12) Patent Application Publication
(10) Pub. No.: US 2026/0158924 A1
(43) Pub. Date: Jun. 11, 2026

(54) IN-VEHICLE SWITCHING DEVICE

(71) Applicant: YAZAKI CORPORATION, Tokyo (JP)

(72) Inventor: Hiroo YABE, Shizuoka (JP)

(73) Assignee: YAZAKI CORPORATION, Tokyo (JP)

(21) Appl. No.: 19/183,456

(22) Filed: Apr. 18, 2025

(30) Foreign Application Priority Data
May 20, 2024 (JP) 2024-081723

(51) Int. Cl. B60L 3/00; B60L 58/19; G01R 31/385

(52) U.S. Cl. CPC B60L 3/0046; B60L 3/0092; B60L 58/19; G01R 31/385; B60L 2240/549

(57) ABSTRACT

A series switch is connected between a negative electrode of a first battery and a positive electrode of a second battery. A first parallel switch is connected between a negative electrode of the second battery and a point that is between the series switch and the negative electrode of the first battery. A second parallel switch is connected between a positive electrode of the first battery and a point that is between the series switch and the positive electrode of the second battery. A first pyro-fuse is connected between the negative electrode of the first battery and a point that is between the series switch and the first parallel switch. A second pyro-fuse is connected between the positive electrode of the second battery and a point that is between the series switch and the second parallel switch.

### CROSS-REFERENCE TO RELATED APPLICATIONS

This application is based on and claims priority under 35 USC 119 from Japanese Patent Application No. 2024-081723 filed on May 20, 2024, the contents of which are incorporated herein by reference.

### TECHNICAL FIELD

The present disclosure relates to an in-vehicle switching device.

### BACKGROUND ART

In the related art, an in-vehicle switching device capable of switching a first battery and a second battery between a series connection state and a parallel connection state is proposed (Patent Literature 1). In the in-vehicle switching device according to Patent Literature 1, a pyro-fuse is provided between a negative electrode of the first battery and a positive electrode of the second battery, and the pyro-fuse is cut when an overcurrent flows.

When the pyro-fuse is cut, power supply from both the first battery and the second battery to a load is cut off. Therefore, there is a problem in which even when one of the first battery and the second battery can still supply power, power supply to the load is stopped, and redundancy cannot be achieved.

### CITATION LIST

### Patent Literature

Patent Literature 1: JP2022-170763A

### SUMMARY OF INVENTION

The present disclosure is made in view of the above circumstance, and an object of the present disclosure is to provide an in-vehicle switching device that improves redundancy.

To achieve the above object, the in-vehicle switching device according to the present disclosure has the following features. The in-vehicle switching device includes a series switch configured to be connected between a negative electrode of a first battery and a positive electrode of a second battery; a first parallel switch configured to be connected between a negative electrode of the second battery and a point that is between the series switch and the negative electrode of the first battery; a second parallel switch configured to be connected between a positive electrode of the first battery and a point that is between the series switch and the positive electrode of the second battery; a first pyro-fuse configured to be connected between the negative electrode of the first battery and a point that is between the series switch and the first parallel switch; and a second pyro-fuse configured to be connected between the positive electrode of the second battery and a point that is between the series switch and the second parallel switch.

According to the in-vehicle switching device according to the present disclosure, an effect of improving redundancy is achieved.

The present disclosure has been briefly described above. Further, the details of the present disclosure can be clarified by reading modes (hereinafter, referred to as “embodiments”) for carrying out the invention to be described below with reference to the accompanying drawings.

### BRIEF DESCRIPTION OF DRAWINGS

FIG. 1 is a circuit diagram showing an embodiment of an in-vehicle power supply system in which an in-vehicle switching device according to the present disclosure is incorporated.

FIG. 2 shows a configuration of a pyro-fuse shown in FIG. 1.

FIG. 3 is a flowchart showing a processing procedure of a control unit shown in FIG. 1 in a first embodiment.

FIG. 4 is a flowchart showing a processing procedure of the control unit shown in FIG. 1 in a second embodiment.

FIGS. 5A and 5B are explanatory diagrams, each of which shows a threshold in an overcurrent state in a case in which each of a first current sensor 21 and a second current sensor shown in FIG. 1 includes both a shunt resistance type current sensor and a Hall type current sensor.

### DESCRIPTION OF EMBODIMENTS

A specific embodiment according to the present disclosure will be described below with reference to the drawings.

### First Embodiment

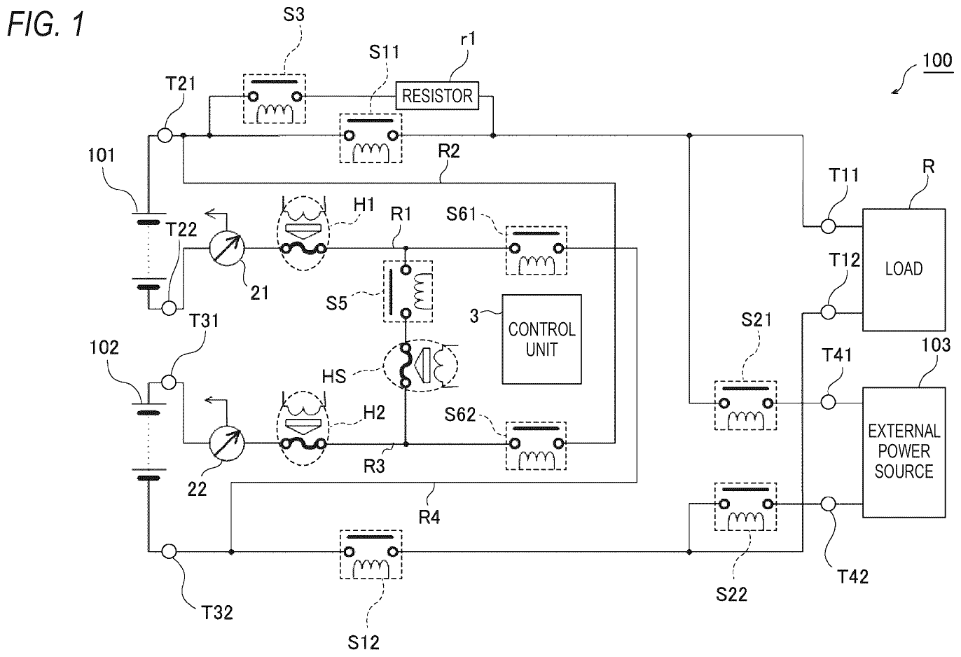

An in-vehicle switching device 1 of a first embodiment will be described. FIG. 1 is a circuit diagram showing an embodiment of an in-vehicle power supply system 100 in which an in-vehicle switching device 1 according to the present disclosure is incorporated. The in-vehicle power supply system 100 includes a load R (for example, a motor that drives wheels), a first battery 101 and a second battery 102 that supply power to the load R, an external power source 103 that charges the first battery 101 and the second battery 102, and the in-vehicle switching device 1 that switches the first battery 101 and the second battery 102 between a series connection state and a parallel connection state.

The in-vehicle switching device 1 includes a high-potential side switch S11, a low-potential side switch S12, a high-potential side power supply switch S21, a low-potential side power supply switch S22, a bypass switch S3, and a resistor r1. The switches S11, S12, S21, S22, and S3 shown in FIG. 1 are constituted by mechanical relays, but may be constituted by semiconductor switches such as MOSFETs.

The high-potential side switch S11 and the low-potential side switch S12 are switches that turn on and off power supply from the first battery 101 and the second battery 102 to the load R, respectively. The high-potential side switch S11 is connected between a terminal T11 connected to one end of the load R and a terminal T21 connected to a positive electrode of the first battery 101. The low-potential side switch S12 is connected between a terminal T12 connected to the other end of the load R and a terminal T32 connected to a negative electrode of the second battery 102.

The high-potential side power supply switch S21 and the low-potential side power supply switch S22 are switches that turn on and off charging from the external power source 103 to the first battery 101 and the second battery 102, respectively. The high-potential side power supply switch S21 is connected between a terminal T41 connected to one end of the external power source 103 and a connection point that is between the terminal T11 and the high-potential side switch S11. The low-potential side power supply switch S22 is connected between a terminal T42 connected to the other end of the external power source 103 and a connection point that is between the terminal T12 and the low-potential side switch S12.

The bypass switch S3 is a switch for bypassing the high-potential side switch S11 and connecting the resistor r1. The bypass switch S3 and the resistor r1 are connected in parallel with the high-potential side switch S11.

The in-vehicle switching device 1 includes a series switch S5, a first parallel switch S61, a second parallel switch S62, a first pyro-fuse H1, a second pyro-fuse H2, and a central pyro-fuse HS. The switches S5, S61, and S62 shown in FIG. 1 are constituted by mechanical relays, but may be constituted by semiconductor switches such as MOSFETs.

The series switch S5 is connected between a terminal T22 connected to a negative electrode of the first battery 101 and a terminal T31 connected to a positive electrode of the second battery 102. The first parallel switch S61 is connected between the terminal T32 connected to the negative electrode of the second battery 102 and a point that is between the series switch S5 and the terminal T22 connected to the negative electrode of the first battery 101. The second parallel switch S62 is connected between the terminal T21 connected to the positive electrode of the first battery 101 and a point that is between the series switch S5 and the terminal T31 connected to the positive electrode of the second battery 102.

When the series switch S5 is turned on and the first parallel switch S61 and the second parallel switch S62 are turned off, the first battery 101 and the second battery 102 are in the series connection state. When the first parallel switch S61 and the second parallel switch S62 are turned on and the series switch S5 is turned off, the first battery 101 and the second battery 102 are in the parallel connection state. The series switch S5, the first parallel switch S61, and the second parallel switch S62 are controlled by a control unit 3 described later to be turned on and off.

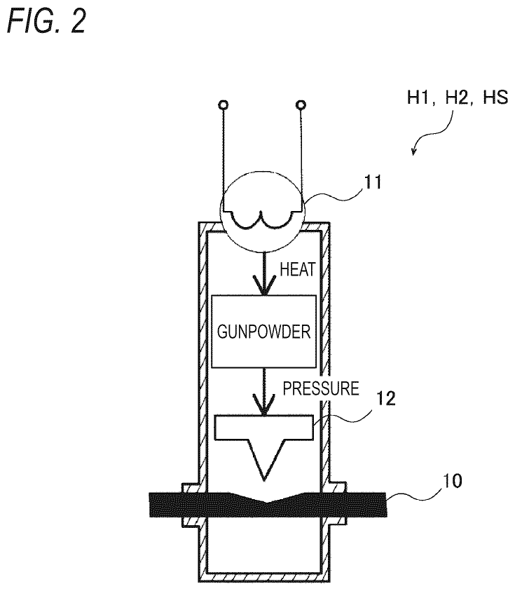

As shown in FIG. 2, each of the pyro-fuses H1, H2, and HS includes a thin plate conductor 10, an igniter 11, and a cutter 12. The thin plate conductor 10 is connected on a path and is provided with a notch. The igniter 11 ignites gunpowder in response to an input of an ignition signal output from the control unit 3 described later. The cutter 12 is pressed by a pressure generated by igniting the gunpowder to approach the thin plate conductor 10 and cut the notch of the thin plate conductor 10.

The first pyro-fuse H1 is connected between the terminal T22 connected to the negative electrode of the first battery 101 and a point that is between the series switch S5 and the first parallel switch S61. The second pyro-fuse H2 is connected between the terminal T31 connected to the positive electrode of the second battery 102 and a point that is between the series switch S5 and the second parallel switch S62.

The central pyro-fuse HS is connected in series with the series switch S5 between the first pyro-fuse H1 and the second pyro-fuse H2.

The in-vehicle switching device 1 includes a first current sensor 21, a second current sensor 22, and a control unit 3. The first current sensor 21 is connected in series with the first pyro-fuse H1 between the terminal T22 connected to the negative electrode of the first battery 101 and a point that is between the first parallel switch S61 and a serial circuit including the series switch S5 and the central pyro-fuse HS. In the present embodiment, the first current sensor 21 is connected closer to the terminal T22 than the first pyro-fuse H1, but may be connected closer to the first parallel switch S61 than the first pyro-fuse H1.

The second current sensor 22 is connected in series with the second pyro-fuse H2 between the terminal T31 connected to the positive electrode of the second battery 102 and a point that is between the second parallel switch S62 and the serial circuit including the series switch S5 and the central pyro-fuse HS. In the present embodiment, the second current sensor 22 is connected closer to the terminal T31 than the second pyro-fuse H2, but may be connected closer to the second parallel switch S62 than the first pyro-fuse H1.

Each of the first current sensor 21 and the second current sensor 22 may include a shunt resistance type current sensor using a shunt resistance, or may include a Hall type current sensor using a Hall element. Each of the first current sensor 21 and the second current sensor 22 may include both the shunt resistance type current sensor and the Hall type current sensor.

The control unit 3 includes, for example, a microcomputer, and outputs the ignition signal to the central pyro-fuse HS, the first pyro-fuse H1, and the second pyro-fuse H2 according to detection values of the first current sensor 21 and the second current sensor 22 to control cutting.

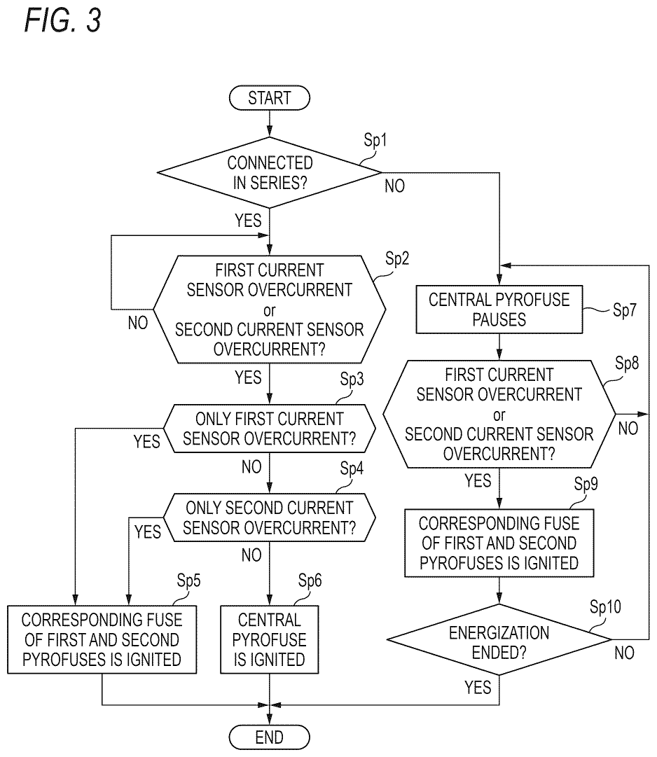

Next, an operation of the in-vehicle switching device 1 having the above configuration will be described with reference to a flowchart in FIG. 3. The control unit 3 starts operating in response to turning on an ignition switch. First, the control unit 3 determines whether the first battery 101 and the second battery 102 are in the series connection state (Sp1). If the control unit 3 determines that the series switch S5 is turned on and the first parallel switch S61 and the second parallel switch S62 are turned off and determines that the first battery 101 and the second battery 102 are in the series connection state (Y in Sp1), the control unit 3 determines whether the detection value of at least one of the first current sensor 21 and the second current sensor 22 indicates an overcurrent state (Sp2).

If the detection value of at least one of the first current sensor 21 and the second current sensor 22 does not indicate the overcurrent state (N in Sp2), the control unit 3 returns to Sp2 and repeatedly performs the determination in Sp2.

Meanwhile, if only the detection value of the first current sensor 21 indicates the overcurrent state and the detection value of the second current sensor 22 does not indicate the overcurrent state (Y in Sp3), the control unit 3 proceeds to Sp5. When the processing proceeds from Sp3 to Sp5, the control unit 3 outputs the ignition signal to the first pyro-fuse H1 corresponding to the first current sensor 21 (Sp5), and ends the processing. For example, when a path R1 and a path R2 shown in FIG. 1 are short-circuited, only the detection value of the first current sensor 21 indicates the overcurrent state, and overcurrent can be cut off by cutting the first pyro-fuse H1. The path R1 is a path between the first pyro-fuse H1 and the series switch S5. The path R2 is a path between the second parallel switch S62 and the terminal T21. When the paths R1 and R2 are short-circuited, the overcurrent cannot be cut off even when the central pyro-fuse HS is cut.

If only the detection value of the second current sensor 22 indicates the overcurrent state and the detection value of the first current sensor 21 does not indicate the overcurrent state (N in Sp3 and Y in Sp4), the control unit 3 proceeds to Sp5. When the processing proceeds from Sp4 to Sp5, the control unit 3 outputs the ignition signal to the second pyro-fuse H2 corresponding to the second current sensor 22 (Sp5), and ends the processing. For example, when a path R3 and a path R4 shown in FIG. 1 are short-circuited, only the detection value of the second current sensor 22 indicates the overcurrent state, and the overcurrent can be cut off by cutting the second pyro-fuse H2. The path R3 is a path between the second pyro-fuse H2 and the series switch S5. The path R4 is a path between the first parallel switch S61 and the terminal T32. When the paths R3 and R4 are short-circuited, the overcurrent cannot be cut off even when the central pyro-fuse HS is cut.

If the detection values of the first current sensor 21 and the second current sensor 22 indicate the overcurrent state (N in Sp4), the control unit 3 outputs the ignition signal to the central pyro-fuse HS (Sp6), and ends the processing. For example, when the paths R2 and R4, the terminals T11 and T12, and the terminals T41 and T42 are short-circuited, the detection values of the first current sensor 21 and the second current sensor 22 indicate the overcurrent state, and the overcurrent can be cut off by cutting the central pyro-fuse HS.

Meanwhile, if the control unit 3 determines that the series switch S5 is turned off and the first parallel switch S61 and the second parallel switch S62 are turned on and determines that the first battery 101 and the second battery 102 are in the parallel connection state (N in Sp1), the control unit 3 does not cut the central pyro-fuse HS (pause) (Sp7). Next, the control unit 3 determines whether the detection value of at least one of the first current sensor 21 and the second current sensor 22 indicates the overcurrent state (Sp8).

Next, the control unit 3 outputs the ignition signal to the first pyro-fuse H1 when the detection value of the first current sensor 21 indicates the overcurrent state, and outputs the ignition signal to the second pyro-fuse H2 when the detection value of the second current sensor 22 indicates the overcurrent state (Sp9). To describe Sp9 in detail, when only the detection value of the first current sensor 21 indicates the overcurrent state and the detection value of the second current sensor 22 does not indicate the overcurrent state, the control unit 3 cuts only the first pyro-fuse H1 and does not cut the second pyro-fuse H2.

As described above, when the path R1 and the path R2 are short-circuited, only the detection value of the first current sensor 21 indicates the overcurrent state, and the overcurrent can be cut off by cutting the first pyro-fuse H1. In addition, since the second pyro-fuse H2 is not cut, power supply from only the second battery 102 to the load R and charging from the external power source 103 can be continued.

To describe Sp9 in detail, when only the detection value of the second current sensor 22 indicates the overcurrent state and the detection value of the first current sensor 21 does not indicate the overcurrent state, the control unit 3 cuts only the second pyro-fuse H2 and does not cut the first pyro-fuse H1. As described above, when the path R3 and the path R4 are short-circuited, only the detection value of the second current sensor 22 indicates the overcurrent state, and the overcurrent can be cut off by cutting the second pyro-fuse H2. In addition, since the first pyro-fuse H1 is not cut, power supply from only the first battery 101 to the load R and charging from the external power source 103 can be continued.

In Sp9, when the detection values of the first current sensor 21 and the second current sensor 22 indicate the overcurrent state, the control unit 3 outputs the ignition signal to both the first pyro-fuse H1 and the second pyro-fuse H2. Thereafter, if the energization is ended (Y in Sp10), the control unit 3 ends the processing. If the energization is not ended (N in Sp10), the control unit 3 returns to Sp8.

According to the embodiment described above, by providing the first pyro-fuse H1 and the second pyro-fuse H2, it is possible to reduce the overcurrent due to a short circuit that cannot be handled by cutting the central pyro-fuse HS, such as the short circuit between the paths R1 and R2 and the short circuit between the paths R3 and R4. When one of the first battery 101 and the second battery 102 is short-circuited and the other is normal, the normal one of the first battery 101 and the second battery 102 can continue supplying power or being charged, and redundancy can be improved.

### Second Embodiment

Next, the in-vehicle switching device 1 according to a second embodiment will be described. The in-vehicle switching device 1 according to the second embodiment has the same configuration as that in the first embodiment, and thus detailed description thereof will be omitted herein.

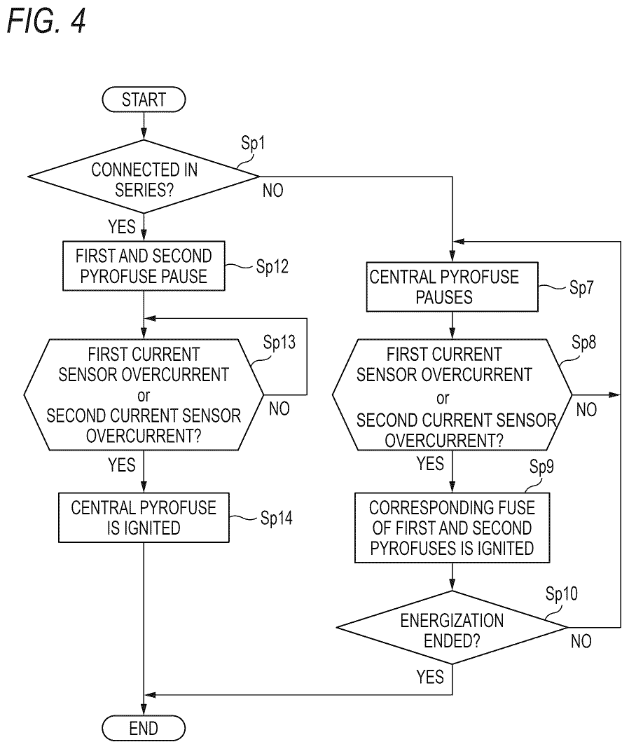

An operation of the second embodiment will be described with reference to FIG. 4. In FIG. 4, the same reference signs are given to parts of the operation which are the same as those in the flowchart shown in FIG. 3 already described in the first embodiment, and the detailed description thereof will be omitted. The control unit 3 starts operating in response to turning on the ignition switch. The control unit 3 starts operating in response to turning on the ignition switch. First, the control unit 3 determines whether the first battery 101 and the second battery 102 are in the series connection state (Sp1). If the control unit 3 determines that the first battery 101 and the second battery 102 are in the series connection state (Y in Sp1), the control unit 3 does not cut the first pyro-fuse H1 and the second pyro-fuse H2 (pause) (SP12).

Next, the control unit 3 determines whether the detection value of at least one of the first current sensor 21 and the second current sensor 22 indicates the overcurrent state (Sp13). If the detection value of at least one of the first current sensor 21 and the second current sensor 22 indicates the overcurrent state (Y in Sp13), the control unit 3 outputs the ignition signal to the central pyro-fuse HS (Sp14), and ends the processing. If the control unit 3 determines that the first battery 101 and the second battery 102 are in the parallel connection state (N in Sp1), the control unit 3 proceeds to Sp7 to Sp10 as in the first embodiment.

The control unit 3 may be operated as shown in FIG. 4 as long as the occurrence of the short circuit between the paths R1 and R2 and the short circuit between the paths R3 and R4 can be reduced by thickening or separating insulating materials between the paths R1 and R2 and insulating materials between the paths R3 and R4. In the second embodiment described above, as in the first embodiment, when one of the first battery 101 and the second battery 102 is short-circuited and the other is normal, the normal one of the first battery 101 and the second battery 102 can continue supplying power or being charged, and the redundancy can be improved.

Next, determination on an overcurrent state in a case in which each of the first current sensor 21 and the second current sensor 22 includes both the shunt resistance type current sensor and the Hall type current sensor will be described. When at least one of the detection value of the shunt resistance type current sensor and the detection value of the Hall type current sensor exceeds a threshold, the control unit 3 may determine that the detection values of the first current sensor 21 and the second current sensor 22 indicate the overcurrent state (OR determination). When both the detection value of the shunt resistance type current sensor and the detection value of the Hall type current sensor exceed the threshold, the control unit 3 may determine that the detection values of the first current sensor 21 and the second current sensor 22 indicate the overcurrent state (AND determination).

The control unit 3 may use the OR determination and the AND determination depending on the series connection state and the parallel connection state. In the series connection state, there is no redundancy, and in the parallel connection state, there is redundancy as described above. Therefore, for example, the control unit 3 preferably performs the AND determination in the case of the series connection state and performs the OR determination in the case of the parallel connection state, but the present disclosure is not limited thereto.

When an average of the detection value of the shunt resistance type current sensor and the detection value of the Hall type current sensor exceeds the threshold, the control unit 3 may determine that the detection values of the first current sensor 21 and the second current sensor 22 indicate the overcurrent state (average determination).

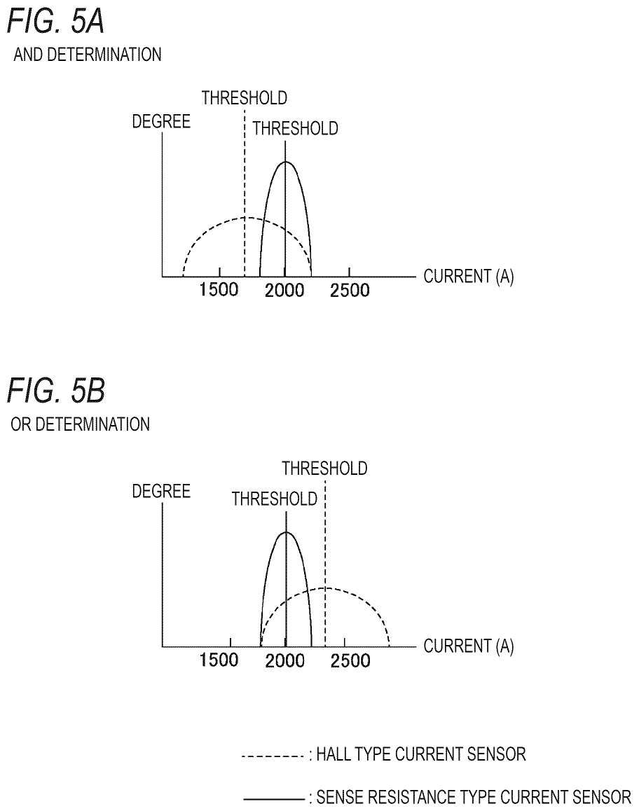

The threshold of the overcurrent state in the case in which each of the first current sensor 21 and the second current sensor 22 includes both the shunt resistance type current sensor and the Hall type current sensor will be described with reference to FIGS. 5A and 5B. FIGS. 5A and 5B are graphs each of which shows a distribution of variations when detection values of the Hall type current sensor and the shunt resistance type current sensor are thresholds. As shown in FIGS. 5A and 5B, the detection value of the Hall type current sensor generally has a variation range larger than that of the detection value of the shunt resistance type current sensor.

As shown in FIG. 5A, when the AND determination is performed, the thresholds are set such that a variation upper limit value when the detection value of the Hall type current sensor is the threshold is equal to or lower than a variation upper limit value when the detection value of the shunt resistance type current sensor is the threshold. In the case shown in FIG. 5A, the threshold of the detection value of the shunt resistance type current sensor is set to 2000 A, and the threshold of the detection value of the Hall type current sensor is set to 1700 A. Accordingly, it is possible to accurately detect the overcurrent state.

As shown in FIG. 5B, when the OR determination is performed, the thresholds are set such that a variation lower limit value when the detection value of the Hall type current sensor is the threshold is equal to or higher than a variation lower limit value when the detection value of the shunt resistance type current sensor is the threshold. In the case shown in FIG. 5B, the threshold of the detection value of the shunt resistance type current sensor is set to 2000 A, and the threshold of the detection value of the Hall type current sensor is set to 2300 A. Accordingly, it is possible to accurately detect the overcurrent state.

The present disclosure is not limited to the embodiments described above and can be appropriately modified, improved, or the like. In addition, materials, shapes, sizes, numbers, arrangement positions, and the like of components in the embodiments described above are freely selected and are not limited as long as the present disclosure can be implemented.

Here, features of the embodiments of the in-vehicle switching device according to the present disclosure described above are briefly summarized and listed in the following [1] to [6].

[1] An in-vehicle switching device (1) including:
a series switch (S5) configured to be connected between a negative electrode of a first battery (101) and a positive electrode of a second battery (102);
a first parallel switch (S61) configured to be connected between a negative electrode of the second battery (102) and a point that is between the series switch (S5) and the negative electrode of the first battery (101);
a second parallel switch (S62) configured to be connected between a positive electrode of the first battery (101) and a point that is between the series switch (S5) and the positive electrode of the second battery (102);
a first pyro-fuse (H1) configured to be connected between the negative electrode of the first battery (101) and a point that is between the series switch (S5) and the first parallel switch (S61); and
a second pyro-fuse (H2) configured to be connected between the positive electrode of the second battery (102) and a point that is between the series switch (S5) and the second parallel switch (S62).

According to the in-vehicle switching device (1) having the configuration of the above [1], by providing the first pyro-fuse (H1) and the second pyro-fuse (H2), when one of the first battery (101) and the second battery (102) is short-circuited and the other is normal, the normal one of the first battery (101) and the second battery (102) can continue supplying power or being charged, and the redundancy can be improved.

[2] The in-vehicle switching device (1) according to [1], further including:
a central pyro-fuse (HS) configured to be connected in series with the series switch (S5) between the first pyro-fuse (H1) and the second pyro-fuse (H2).

According to the in-vehicle switching device (1) having the above configuration of the above [2], by providing the central pyro-fuse (HS), when the first battery (101) and the second battery (102) are in the series connection state, the overcurrent may be reduced by cutting only the central pyro-fuse (HS) without cutting both the first pyro-fuse (H1) and the second pyro-fuse (H2).

[3] The in-vehicle switching device (1) according to [2], further including:
a first current sensor (21) configured to be connected in series with the first pyro-fuse (H1) between the negative electrode of the first battery (101) and a point that is between the first parallel switch (S61) and a series circuit including the series switch (S5) and the central pyro-fuse (HS);
a second current sensor (22) configured to be connected in series with the second pyro-fuse (H2) between the positive electrode of the second battery (102) and a point that is between the second parallel switch (S62) and the series circuit including the series switch (S5) and the central pyro-fuse (HS); and
a control unit (3) configured to control cutting of the central pyro-fuse (HS), the first pyro-fuse (H1), and the second pyro-fuse (H2) according to detection values of the first current sensor (21) and the second current sensor (22).

According to the in-vehicle switching device (1) having the configuration of the above [3], the cutting of the central pyro-fuse (HS), the first pyro-fuse (H1), and the second pyro-fuse (H2) is controlled according to the detection values of the first current sensor (21) and the second current sensor (22). Accordingly, it is possible to cut an appropriate portion among the central pyro-fuse (HS), the first pyro-fuse (H1), and the second pyro-fuse (H2) depending on a short-circuited portion.

[4] The in-vehicle switching device (1) according to [3], in which
the control unit
   in a case in which the series switch (S5) is turned on, cuts the first pyro-fuse (H1) when only the detection value of the first current sensor (21) indicates an overcurrent state, cuts the second pyro-fuse (H2) when only the detection value of the second current sensor (22) indicates the overcurrent state, and cuts the central pyro-fuse (HS) when both the detection values of the first current sensor (21) and the second current sensor (22) indicate the overcurrent state, and
   in a case in which the first parallel switch (S61) and the second parallel switch (S62) are turned on, cuts the first pyro-fuse (H1) when the detection value of the first current sensor (21) indicates the overcurrent state, cuts the second pyro-fuse (H2) when the detection value of the second current sensor (22) indicates the overcurrent state, and does not cut the central pyro-fuse (HS).

According to the in-vehicle switching device (1) having the configuration of the above [4], it is possible to cut an appropriate portion among the central pyro-fuse (HS), the first pyro-fuse (H1), and the second pyro-fuse (H2) depending on a short-circuited portion. In the case of the parallel connection, when one of the first battery (101) and the second battery (102) is short-circuited and the other is normal, the normal one of the first battery (101) and the second battery (102) can continue supplying power or being charged.

[5] The in-vehicle switching device (1) according to [3], in which
the control unit (3)
   in a case in which the series switch (S5) is turned on, cuts the central pyro-fuse (HS) when the detection value of at least one of the first current sensor (21) and the second current sensor (22) indicates an overcurrent state, and does not cut the first pyro-fuse (H1) and the second pyro-fuse (H2), and
   in a case in which the first parallel switch (S61) and the second parallel switch (S62) are turned on, cuts the first pyro-fuse (H1) when the detection value of the first current sensor (21) indicates the overcurrent state, cuts the second pyro-fuse (H2) when the detection value of the second current sensor (22) indicates the overcurrent state, and does not cut the central pyro-fuse (HS).

According to the in-vehicle switching device (1) having the configuration of the above [5], in the case of the series connection, it is possible to easily reduce the overcurrent by cutting only the central pyro-fuse (HS). In the case of the parallel connection, when one of the first battery (101) and the second battery (102) is short-circuited and the other is normal, the normal one of the first battery (101) and the second battery (102) can continue supplying power or being charged.

[6] The in-vehicle switching device (1) according to [3], in which
each of the first current sensor (21) and the second current sensor (22) includes a sense resistance type current sensor and a Hall type current sensor, and
the control unit (3)
   in a case in which the series switch (S5) is turned on, determines that the detection value of the first current sensor (21) or the second current sensor (22) including the sense resistance type current sensor and the Hall type current sensor indicates an overcurrent state when the detection values of both the sense resistance type current sensor and the Hall type current sensor indicate the overcurrent state, and
   in a case in which the first parallel switch (S61) and the second parallel switch (S62) are turned on, determines that the detection value of the first current sensor (21) or the second current sensor (22) including the sense resistance type current sensor and the Hall type current sensor indicates the overcurrent state when at least one of the detection values of the sense resistance type current sensor and the Hall type current sensor indicates the overcurrent state.

According to the in-vehicle switching device (1) having the configuration of the above [6], in the series connection state without redundancy, the overcurrent state can be determined by the AND determination performed for the sense resistance type current sensor and the Hall type current sensor, and in the parallel connection state with redundancy, the overcurrent state can be determined by the OR determination performed for the sense resistance type current sensor and the Hall type current sensor.

What is claimed is:

1. An in-vehicle switching device comprising:
a series switch configured to be connected between a negative electrode of a first battery and a positive electrode of a second battery;
a first parallel switch configured to be connected between a negative electrode of the second battery and a point that is between the series switch and the negative electrode of the first battery;
a second parallel switch configured to be connected between a positive electrode of the first battery and a point that is between the series switch and the positive electrode of the second battery;
a first pyro-fuse configured to be connected between the negative electrode of the first battery and a point that is between the series switch and the first parallel switch; and
a second pyro-fuse configured to be connected between the positive electrode of the second battery and a point that is between the series switch and the second parallel switch.

2. The in-vehicle switching device according to claim 1, further comprising:
a central pyro-fuse configured to be connected in series with the series switch between the first pyro-fuse and the second pyro-fuse.

3. The in-vehicle switching device according to claim 2, further comprising:
a first current sensor configured to be connected in series with the first pyro-fuse between the negative electrode of the first battery and a point that is between the first parallel switch and a series circuit including the series switch and the central pyro-fuse;
a second current sensor configured to be connected in series with the second pyro-fuse between the positive electrode of the second battery and a point that is between the second parallel switch and the series circuit including the series switch and the central pyro-fuse; and
a control unit configured to control cutting of the central pyro-fuse, the first pyro-fuse, and the second pyro-fuse according to detection values of the first current sensor and the second current sensor.

4. The in-vehicle switching device according to claim 3, wherein
in a case in which the series switch is turned on, the control unit cuts the first pyro-fuse when only the detection value of the first current sensor indicates an overcurrent state, cuts the second pyro-fuse when only the detection value of the second current sensor indicates the overcurrent state, and cuts the central pyro-fuse when both the detection values of the first current sensor and the second current sensor indicate the overcurrent state, and
in a case in which the first parallel switch and the second parallel switch are turned on, the control unit cuts the first pyro-fuse when the detection value of the first current sensor indicates the overcurrent state, cuts the second pyro-fuse when the detection value of the second current sensor indicates the overcurrent state, and does not cut the central pyro-fuse.

5. The in-vehicle switching device according to claim 3, wherein
in a case in which the series switch is turned on, the control unit cuts the central pyro-fuse when the detection value of at least one of the first current sensor and the second current sensor indicates an overcurrent state, and does not cut the first pyro-fuse and the second pyro-fuse, and
in a case in which the first parallel switch and the second parallel switch are turned on, the control unit cuts the first pyro-fuse when the detection value of the first current sensor indicates the overcurrent state, cuts the second pyro-fuse when the detection value of the second current sensor indicates the overcurrent state, and does not cut the central pyro-fuse.

6. The in-vehicle switching device according to claim 3, wherein
each of the first current sensor and the second current sensor includes a sense resistance type current sensor and a Hall type current sensor, and
in a case in which the series switch is turned on, the control unit determines that the detection value of the first current sensor or the second current sensor including the sense resistance type current sensor and the Hall type current sensor indicates an overcurrent state when the detection values of both the sense resistance type current sensor and the Hall type current sensor indicate the overcurrent state, and
in a case in which the first parallel switch and the second parallel switch are turned on, the control unit determines that the detection value of the first current sensor or the second current sensor including the sense resistance type current sensor and the Hall type current sensor indicates the overcurrent state when at least one of the detection values of the sense resistance type current sensor and the Hall type current sensor indicates the overcurrent state.
